(19) United States
(12) Patent Application Publication
(10) Pub. No.: US 2025/0293902 A1
(43) Pub. Date: Sep. 18, 2025

(54) CLOCK FORWARDED MATCHED RECEIVER WITH DECISION FEEDBACK EQUALIZER

(71) Applicant: RENESAS ELECTRONICS AMERICA INC., MILPITAS, CA (US)

(72) Inventor: Steven Ernest FINN, Atlanta, GA (US)

(73) Assignee: RENESAS ELECTRONICS AMERICA INC., MILPITAS, CA (US)

(21) Appl. No.: 18/607,409

(22) Filed: Mar. 15, 2024

(51) Int. Cl. H04L 25/03; H04L 1/00

(52) U.S. Cl. CPC H04L 25/03076; H04L 1/0041

(57) ABSTRACT

Systems and methods for clock forwarded matched receiver with decision feedback equalizer are described. A system can include a controller to generate a strobe signal and a transmitter to output an analog signal. The system can include a receiver to receive the analog signal from the transmitter through a channel. The receiver can apply a positive offset to the analog signal to generate a first internal signal and apply a negative offset to the analog signal to generate a second internal signal. The receiver can sample at least one of the first internal signal and the second internal signal according to the strobe signal. The receiver can use a previous digital signal as a selection signal to select a specific signal that decodes the analog signal and based on the sample and the selection, generate a digital signal that represents a decoded bit value of the analog signal.

### BACKGROUND

The present disclosure relates in general to apparatuses and methods for clock forwarded matched receiver with decision feedback equalizer in memory devices.

Data signals can be transferred from a transmitter to a receiver across a channel in a memory device. Channels can introduce impairments such as attenuation, reflection, and noise, leading to transmission errors and impacting data speed rates. To mitigate the effects of Inter-Symbol Interference (ISI) and flatten the frequency response of communication media, an adaptive filtering process, known as equalization, can be employed. Decision Feedback Equalization (DFE) architecture is a common filtering approach used for this purpose.

### SUMMARY

In one embodiment, an integrated circuit that can implement clock forwarded matched receiver with decision feedback equalizer is generally described. The integrated circuit can include a first summation circuit configured to receive an analog signal. The first summation circuit can be further configured to apply a positive offset to the analog signal to generate a first internal signal. The integrated circuit can further include a second summation circuit configured to receive the analog signal. The second summation circuit can be further configured to apply a negative offset to the analog signal to generate a second internal signal. The integrated circuit can further include a first slicer configured to sample the first internal signal to generate a first digital signal. The integrated circuit can further include a second slicer configured to sample the second internal signal to generate a second digital signal. The integrated circuit can further include a multiplexer configured to receive a selection signal. The selection signal can be feedback of a previous digital signal outputted by the multiplexer. The multiplexer can be further configured to select a specific signal between the first digital signal and the second digital signal. The multiplexer can be further configured to output the selected specific signal as a digital signal that represents a decoded bit value of the analog signal.

In one embodiment, an integrated circuit that can implement clock forwarded matched receiver with decision feedback equalizer is generally described. The integrated circuit can include a first summation circuit configured to receive an analog signal. The first summation circuit can be further configured to apply a positive offset to the analog signal to generate a first internal signal. The integrated circuit can further include a second summation circuit configured to receive the analog signal. The second summation circuit can be further configured to apply a negative offset to the analog signal to generate a second internal signal. The integrated circuit can further include a multiplexer configured to receive a selection signal. The selection signal can be feedback of a previous digital signal outputted by the multiplexer. The multiplexer can be further configured to select one of the first internal signal and the second internal signal. The multiplexer can be further configured to output the selected one of the first internal signal and the second internal signal as a third internal signal. The integrated circuit can further include a slicer configured to sample the third internal signal to generate a digital signal that represents a decoded bit value of the analog signal.

In one embodiment, a system that can implement clock forwarded matched receiver with decision feedback equalizer is generally described. The system can include a controller configured to generate a strobe signal. The system can further include a transmitter configured to output an analog signal. The system can further include a receiver configured to receive the analog signal from the transmitter through a channel. The receiver can be further configured to apply a positive offset to the analog signal to generate a first internal signal. The receiver can be further configured to apply a negative offset to the analog signal to generate a second internal signal. The receiver can be further configured to sample at least one of the first internal signal and the second internal signal according to the strobe signal. The receiver can be further configured to use a previous digital signal as a selection signal to select a specific signal that decodes the analog signal. The receiver can be further configured to, based on the sample and the selection, generate a digital signal that represents a decoded bit value of the analog signal.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram showing an example system that can implement clock forwarded matched receiver with decision feedback equalizer in one embodiment.

FIG. 2 is a diagram showing an example circuit that can implement clock forwarded matched receiver with decision feedback equalizer in one embodiment.

FIG. 3 is diagram showing another example circuit that can implement clock forwarded matched receiver with decision feedback equalizer in another embodiment.

FIG. 4 is a flow diagram illustrating a process to implement clock forwarded matched receiver with decision feedback equalizer in one embodiment.

FIG. 5 is a flow diagram illustrating another process to implement clock forwarded matched receiver with decision feedback equalizer in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Semiconductors are commonly used to store data as memory. Random access memory (RAM) is used is personal computers, servers, etc. to allow the processor to access any part of the memory directly rather than sequentially from a starting place. Different types of RAM include static random access memory (SRAM) and dynamic random access memory (DRAM). With DRAM, the storage cells, consisting of capacitors and transistors, need to be refreshed or given a new electronic charge every few milliseconds to compensate for charge leaks from the capacitor. High-speed communication of data and control signals are necessary to enable the processor to access, read, and write data in memory. A double data rate (DDR) system can be used to increase the communication efficiency by doubling the transfer data. DDR systems use both the rising and falling edges of the clock signal to transfer data twice per clock cycle with a clock speed of at least 200 Megahertz (MHz).

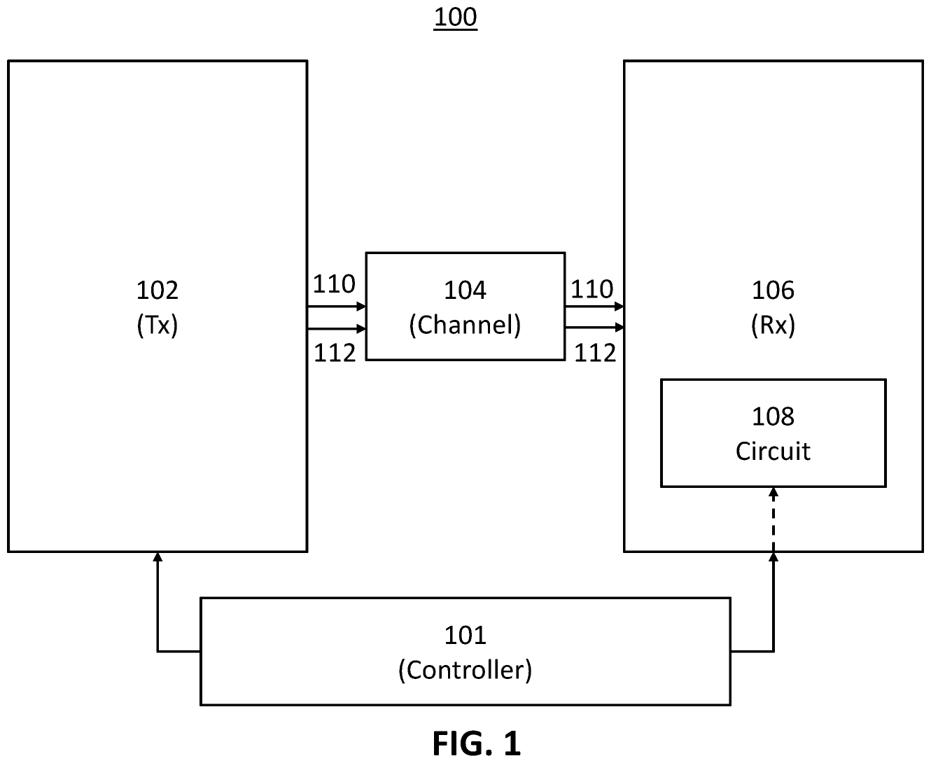

FIG. 1 is diagram showing an example system that can implement clock forwarded matched receiver with decision feedback equalizer (DFE) in one embodiment. System 100 can be a memory system configured to manage data being transferred to and from a memory device such as double data rate 5 synchronous dynamic random-access memory (DDR5 SDRAM) or previous generations (e.g., DDR4 SDRAM). System 100 can include at least a controller 101, a transmitter 102, a channel 104, a receiver 106. Controller 101 can be configured to control, operate, and communicate with both the transmitter 102 and receiver 106 and other components within system 100. Controller 101 can include, for example, a processor, central processing unit (CPU), field-programmable gate array (FPGA) or any other circuitry that is configured to control and operate transmitter 102 and receiver 106. While described as a CPU in illustrative embodiments, controller 101 is not limited to a CPU in these embodiments and may comprise any other circuitry that is configured to control and operate transmitter 102 and receiver 106. In an example embodiment, system 100 can be a memory system of a memory device and controller 101 can be a memory controller configured to manage the data transmitted by the memory device, received by the memory device, and coordinate the timing and synchronization of the data being transferred to and from the memory device.

Transmitter 102 can be configured to encode data bits in analog signals 110 and transmit analog signals to the receiver 106, via channel 104. The transmitter 102 can transform digital data bits into electrical or analog signals suitable for transmission. Transmitter 102 can be configured to also transmit strobe signals 112 as digital signals to the receiver 106, via channel 104. Channel 104 can be a medium configured to facilitate transfer of the electrical signals from transmitter 102 to receiver 106. Channel 104 can include various components such as wires, transmission lines, printed circuit board (PCB) traces, matching networks, or other components that facilitates transmission of electrical signal from transmitter 102 to receiver 106. Receiver 106 can be configured to receive the electrical signals transmitted through the channel 104 from transmitter 102. Receiver 106 can be configured to decode the data bits that was encoded in the received analog signals, such as by demodulating the received analog signals.

In an aspect, memory bandwidth challenges arise as processor core speeds and the number of processing cores per processor increases. The characteristics of channel 104 can introduce noise and interference into the analog signals being transmitted to receiver 106. This noise and interference can cause the analog signals received by receiver 106 to be different from the analog signals that were outputted by transmitter 102 and limit the memory bandwidth. For example, the inherent resistance of the wires (e.g., copper traces) that carry the signal causes energy loss, weakening the signal as it travels across the channel 104. The insulating material surrounding the channel 104 wires can also absorb some of the signal's energy further reducing the transmitted signal strength. Furthermore, the channel 104 does not amplify all frequencies equally. Different frequencies are amplified differently, leading to distortion in the original signal shape. When multiple distorted signal components overlap, they interfere with each other, creating false transitions and corrupting the data known as intersymbol interference (ISI) or intermodulation distortion. As a result of ISI, the timing of the signal transitions becomes dependent on the data pattern being transmitted. This makes it difficult to accurately sample the signal and recover the original data. For example, a graphical representation of the signal quality can result in a ‘closed eye’ diagram, making it difficult to distinguish between different data values, leading to errors in data reception.

In an aspect, the demodulation performed by receiver 106 can use various components, such as analog to digital converters (ADC), decision feedback equalizers (DFEs), or other components, to decode the data and to remove any noise and interference that may have been introduced by channel 104. Furthermore, DDR applications require a matched path between the analog signals 110 and strobe signals 112 at the pins of the receiver 106. The matching can be difficult to achieve because one strobe receiver is shared for multiple data pins leading to internal routing delays. These routing delays can be compensated by adding delay after the data pin receiver. In order to address both the channel impairments and matching between analog signals 110 and strobe signals 112, a clock forwarded matched receiver with DFE can be implemented. Single-tap DFE with feedback signals can be used to improve the integrity of the signal. However, due to signal delays and the aforementioned data matching requirements, it is difficult to align the strobe signal 112 to the center of the analog signals 110. Conventional DFEs attempt to address the signal delays by adding a delay in the strobe signals 112. However, due to the magnitude of the delays, the required strobe signals 112 and analog signals 110 alignment cannot be achieved by strobe delay alone for a matched receiver application such as is required in a DDR. To address this problem, conventional DFEs can utilize strobe signals 112 coming from the transmitter 102 prelaunched by one clock cycle to permit large on-chip physical and routing delays. However, this prelaunch strategy introduces additional offset between the strobe signals 112 and analog signals 110 paths and thereby increases susceptibility to noise and differences between the data and strobe paths. To be described in more detail below, receiver 106 can include a circuit 108 configured to implement a single-tap DFE to enhance the signal integrity by removing the feedback delay, while also utilizing delay lines to align the analog signals 110 and strobe signals 112. The removal of the feedback delay can maintain the signal integrity while improving various performance parameters such as data accuracy, system performance, memory bandwidth, and/or other performance parameters.

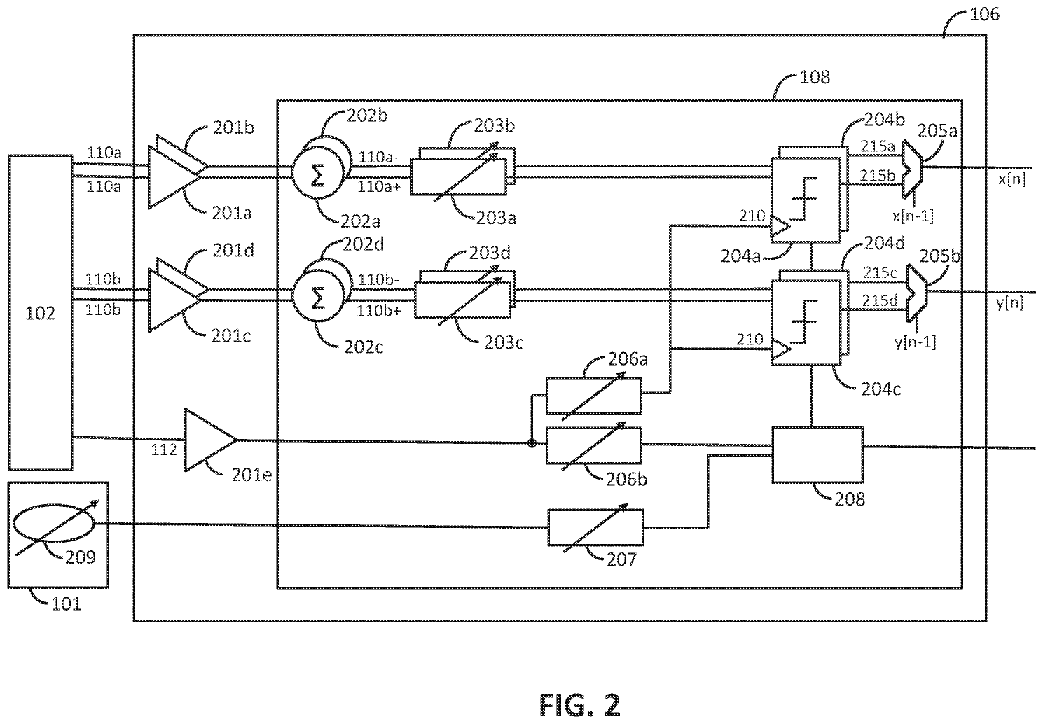

FIG. 2 is diagram showing an example circuit that can implement clock forwarded matched receiver with DFE in another embodiment. Circuit 108 can be, for example, an integrated circuit (IC) configured to implement a single-tap DFE. In one embodiment, circuit 108 can include receivers 201a, 201b, 201c, 201d, and 201e (hereinafter '201). An analog signal 110a is input at receivers 201a and 201b and an analog signal 110b is input at receivers 201c and 201d. Analog signals 110a, 110b can be collectively referred to as analog signals 110 herein. Transmitter 102 can be configured to generate analog signals 110, via channel 104, for receivers 201a-201d. Receivers 201a, 201b, 201c, and 201d can be memory facing data lines configured to receive analog signals 110 and can include various circuit elements, such as buffers, amplifiers, to transfer the signal to circuit 108. In one embodiment, each pair of receivers 201 that receive the same analog signal can be considered as one signal path. By way of example, receivers 201a, 201b can be a first signal path that receives a single ended signal (e.g., analog signal 110a) and receivers 201c, 201d can be a second signal path that receives another single ended signal (e.g., analog signal 110b). In another embodiment, analog signals 110 can be differential signals such that each pair of receivers 201 can receive complementary signals of a differential signal. By way of example, receiver 201a can receive a first signal and receiver 201b can receive a second signal having same magnitude as the first signal but with opposite polarity from the first signal.

Circuit 108 can include DFE summers (or summation circuits) 202a, 202b, 202c, and 202d (hereinafter '202). Circuit 108 can further include delay lines 203a, 203b, 203c, and 203d (hereinafter '203), delay lines 206a and 206b (hereinafter '206) and delay line 207. Delay lines 203, 206, 207 can apply different amounts of delays. By way of example, delay lines 203 can apply a 6-bit delay, delay lines 206 can apply an 8-bit delay and delay lines 207 can apply a 3-bit delay. Circuit 108 can further include slicers 204a, 204b, 204c, 204d (hereinafter '204) and multiplexers 205a and 205b (hereinafter '205). Circuit 108 can further include an enable circuit 208. Controller 101 can include a clock generator 209 configured to generate clock signals to be used by circuit 108. Enable circuit 208 can be configured to selectively enable one or more receivers 201.

Transmitter 102 can be configured to generate strobe signal 112, via channel 104, for circuit 108, where the strobe signals 112 can be received at strobe receiver 201e. Receivers 201a and 201b analog signal can be connected to DFE summers 202a and 202b, respectively. DFE summers 202a, 202b can be connected to slicers 204a, 204b via delay lines 203a and 203b, respectively. Slicers 204a and 204b can be connected to a multiplexer 205a. On the other hand, receivers 201c and 201d can be connected to DFE summers 202c and 202d, respectively. DFE summers 202c, 202d can be connected to slicers 204c, 204d via delay lines 203c and 203d, respectively. Slicers 204c and 204d can be connected to a multiplexer 205b.

In one example embodiment, analog signal 110a can be provided to DFE summers 202a, 202b. DFE summer 202a can be configured to apply a positive offset to analog signal 110a to generate an internal signal 110a+. In one embodiment, DFE summer 202a can apply the positive offset by adding a predefined offset value to analog signal 110a. DFE summer 202b can be configured to apply a negative offset to analog signal 110a to generate an internal signal 110a−. In one embodiment, DFE summer 202a can apply the negative offset by subtracting the predefined offset value from analog signal 110a. Analog signal 110b can be a different analog signal from analog signal 110a, and analog signal 110b can be provided to DFE summers 202c, 202d. DFE summer 202c can be configured to apply a positive coefficient to analog signal 110b to generate an internal signal 110b+. DFE summer 202d can be configured to apply a negative coefficient to analog signal 110b to generate an internal signal 110b−.

Delay lines 203 are configured to delay the analog signals outputted by the corresponding DFE summer 202. By way of example, delay line 203a can apply a delay on internal signal 110a+ and delay line 203b can apply the same delay on internal signal 110a−, before internal signals 110a+, 110− reach slicers 204a, 204b, respectively. The delay applied by delay lines 203 can be configured to any set time, such as a 6 picosecond delay analog signal. Each one of slicers 204 can be a circuit configured to sample an input signal based on strobe signal 112 in order to estimate whether the input internal signal (e.g., 110a+, 110a−, 110b+, 110b−) shall be decoded as a high (binary one) signal or a low (binary zero) signal. The estimation made by slicers 204 can be outputted as binary values 215 (including 215a, 215b, 215c, 215d . . . ). Multiplexers 205 can be configured to select one of two binary values 215 outputted by two slicers 204 and the selected binary value can be outputted as an n-th bit. The selection made by multiplexer 205 can be based on a previous bit outputted by multiplexer 205, such as an (n−1)th bit. Each slicer 204 also receives strobe signal 112 generated by transmitter 102. Delay line 206a can apply a delay to strobe signal 112 before strobe signal 112 reaches the slicers 204. Delay line 206b can apply a delay before strobe signal 112 reaches the enable circuit 208. Delay line 207 can apply a delay on strobe signal 112 before strobe signal reaches the enable circuit 208.

Using slicer 204a and slicer 204b as examples, slicer 204a can receive internal signal 110a+ and slicer 204b can receive signal internal 110a−. Slicer 204a can sample internal signal 110a+ based on the strobe signal 112 and slicer 204b can sample internal signal 110a− based on the strobe signal 112. In an example, slicer 204a can compare the sampled data value from internal signal 110a+ to a reference voltage and outputs a digital signal 215a based on an outcome of the comparison. By way of example, if a voltage of internal signal 110a+ is greater than the reference voltage, then slicer 204a can produce a digital signal 215a as a +1 or a high voltage. If the voltage of internal signal 110a+ is less than the reference voltage, then slicer 204a can produce digital signal 215a as a −1 or a low voltage.

Slicer 204a can provide binary signal 215a to multiplexer 205a. Slicer 204b can function similarly to slicer 204a and can provide a digital signal 215b to multiplexer 205a. Multiplexer 205a use a feedback of a previous output digital signal x[n−1] (e.g., from multiplexer 205a) as a selection signal. According to a value of x[n−1], multiplexer 205a can select one of the two digital signals 215a and 215b as an output digital signal x[n]. The digital signal x[n] can be a digital value that represents a decoded bit value of the received analog signal on the corresponding signal path, which is analog signal 110a in this example. By way of example, if x[n−1] is a high voltage, multiplexer 205a can select digital 215a corresponding to internal signal 110a+ (e.g., the signal applied with the positive offset). By using two DFE summers to apply both positive and negative offsets to the input analog signals, feedback of the output from the slicers to the DFE summers may not be needed, hence removing feedback delay. Removal of the feedback delay (i.e., loop unrolled) allows the analog signal 110 and strobe signal 112 to be aligned using delay lines 203 in the data paths and the strobe signal path without a need to add extra delays to account for delays caused by feedback lines from the slicers to the summers in conventional systems.

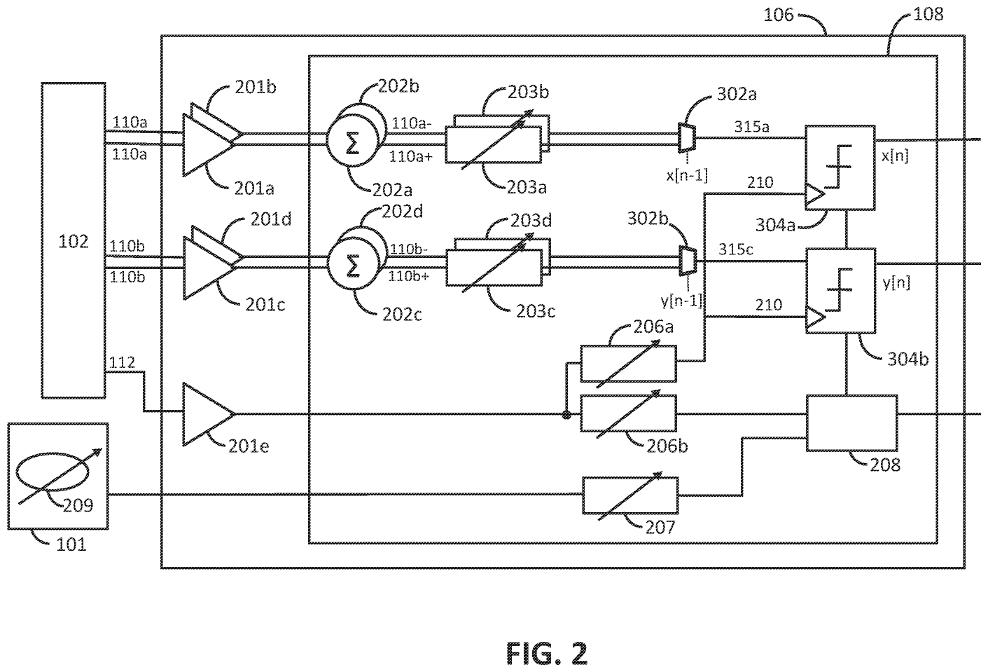

FIG. 3 is diagram showing another example circuit that can implement clock forwarded matched receiver with DFE in another embodiment. Descriptions of FIG. 3 may reference components shown in FIG. 1 to FIG. 3. Circuit 108 can implement a single tap DFE. In one embodiment, circuit 108 can include two slicers 304a and 304b (hereinafter ‘304’) and multiplexers 302a and 302b (hereinafter '302). In the example embodiment shown in FIG. 3, DFE summers 202a, 202b can be connected to multiplexer 302a via delays lines 203a, 203b, respectively. The multiplexer 302a can be connected between DFE summers 202a, 202b and a slicer 304a. DFE summers 202c, 202d can be connected to multiplexer 302b via delay lines 203a and 203b. The multiplexer 302b can be connected between DFE summers 202c, 202c and a slicer 304b.

Also, in the example embodiment shown in FIG. 3, after DFE summers 202a, 202b apply positive and negative offsets to generate internal signals (e.g., 110a+ and 110a−), multiplexer 302a can receive the internal signals 110a+ and 110a− with delays applied by delay lines 203a, 203b. After DFE summers 202c, 202d apply positive and negative offsets to internal signals (e.g., 110b+ and 110b−), multiplexer 302a can receive internal signals 110b+ and 110b− with delays applied by delay lines 203c, 203d.

Multiplexer 302a can also receive a feedback of a previous output digital signal x[n−1] from slicer 304a as a selection signal. According to a value of x[n−1], multiplexer 302a can select one of the two signals 110a+, 110a− as an internal signal or an analog signal 315a. By way of example, if digital signal x[n−1] is a high voltage, multiplexer 302a can select internal signal 110a+ (e.g., signal applied with the positive offset) to output as analog signal 315a for slicer 304a. Slicer 304a can sample the selected signal, such as signal 315a in this example, based on the strobe signal 112. Slicer 304a can compare the sampled data value from analog signal 315a to a reference voltage and outputs a digital signal x[n] based on an outcome of the comparison. The digital signal x[n] can be an output of the n-th clock cycle, and the digital signal x[n−1] can be an output of a clock cycle previous to the n-th clock cycle, such as the (n−1)-th clock cycle. By way of example, if a voltage of analog signal 315a is greater than the reference voltage, then slicer 304a can produce a digital signal x[n] as a +1 or a high voltage. If the voltage of signal 315a is less than the reference voltage, then slicer 304a can produce digital signal x[n] as a −1 or a low voltage. Multiplexer 302b can function in a similar manner as multiplexer 302a to select one of signals 110c, 110d as internal signals for slicer 304b to sample according to strobe signal 112 and for generating another digital signal y[n].

The embodiment in FIG. 3 can occupy less circuit board space when compared to the embodiment in FIG. 2 since one slicer is being used for every signal path (e.g., a pair of receivers 201 receiving the same analog can be a single signal path). The embodiment in FIG. 2, when compared to the embodiment in FIG. 3, can provide better timing performance since the sampling by the slicers is done before the selection by multiplexers, thus there are less delays before the slicer sampling. Therefore, the techniques described herein can provide flexibility on implementation for different types of applications, such as implementing the embodiment of FIG. 2 for better timing performance when circuit board space is less of a concern, or implementing the embodiment of FIG. 3 when circuit board space is a concern.

The techniques described in the present disclosure can remove feedback from the slicer output to DFE summer. The removal of the feedback can eliminate delays that can be introduced by the delay. Delays being applied to the DFE summer outputs and the strobe signal can be controlled without a need to compensate the feedback delay, thus reducing mismatch between the DFE summer output and the strobe signal. The reduced mismatch can eliminate the need for prelaunch of the strobe signal, which can also reduce MDQS distribution power.

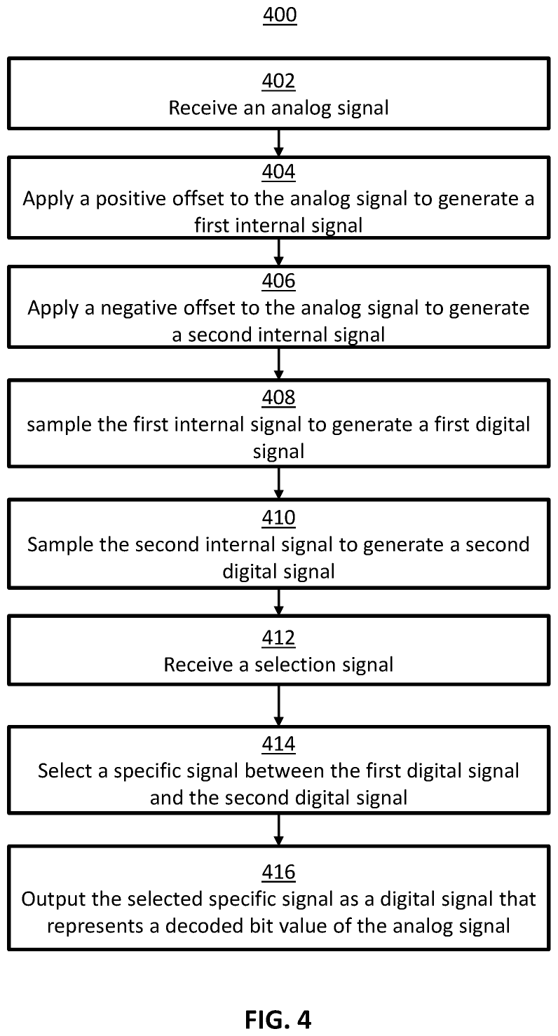

FIG. 4 is a flow diagram illustrating a process to implement clock forwarded matched receiver with decision feedback equalizer in one embodiment. Description of FIG. 4 can reference components shown in FIG. 1 to FIG. 3. The process 400 can include one or more operations, actions, or functions as illustrated by one or more of blocks 402, 404, 406, 408, 410, 412, 414 and/or 416. Although illustrated as discrete blocks, various blocks may be divided into additional blocks, combined into fewer blocks, eliminated, performed in different order, or performed in parallel, depending on the desired implementation.

Process 400 can be performed by a receiver in a memory, such as receiver 106 that includes circuit 108 described herein. Process 400 can begin at block 402. At block 402, the receiver can receive an analog signal. In one embodiment, the analog signal can be a single ended signal. In one embodiment, the analog signal can be a differential signal.

Process 400 can proceed from block 402 to block 404. At block 404, the receiver can apply a positive offset to the analog signal to generate a first internal signal. Process 400 can proceed from block 404 to block 406. At block 406, the receiver can apply a negative offset to the analog signal to generate a second internal signal. In one embodiment, applying the positive offset to the analog signal can include adding a predefined offset to the analog signal, and applying the negative offset to the analog signal can include subtracting the predefined offset from the analog signal.

Process 400 can proceed from block 406 to block 408. At block 408, the receiver can sample the first internal signal to generate a first digital signal. Process 400 can proceed from block 408 to block 410. At block 410, the receiver can sample the second internal signal to generate a second digital signal. In one embodiment, the receiver can apply a first delay to the first internal signal, apply the first delay to the second internal signal, and apply a second delay to a strobe signal being used for sampling the first internal signal and the second internal signal. In one embodiment, the receiver can sample the first internal signal according to a strobe signal and sample the second internal signal according to the strobe signal.

Process 400 can proceed from block 410 to block 412. At block 412, the receiver can receive a selection signal. The selection signal can be a feedback of a previous digital signal outputted by the multiplexer. Process 400 can proceed from block 412 to block 414. At block 414, the receiver can select a specific signal between the first digital signal and the second digital signal. In one embodiment, the receiver can, in response to the previous digital signal indicating a high voltage, select the first digital signal. The receiver can further, in response to the previous digital signal indicating a low voltage, select the second digital signal. Process 400 can proceed from block 414 to block 416. At block 416, the receiver can output the selected specific signal as a digital signal that represents a decoded bit value of the analog signal.

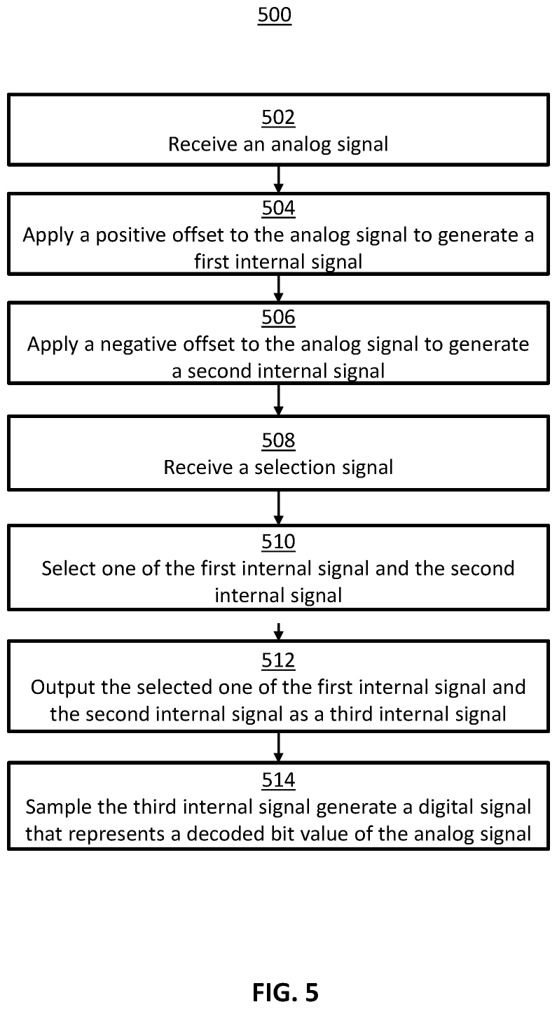

FIG. 5 is a flow diagram illustrating another process to implement clock forwarded matched receiver with decision feedback equalizer in one embodiment. Description of FIG. 5 can reference components shown in FIG. 1 to FIG. 3. The process 500 can include one or more operations, actions, or functions as illustrated by one or more of blocks 502, 504, 506, 508, 510, 512, and/or 516. Although illustrated as discrete blocks, various blocks may be divided into additional blocks, combined into fewer blocks, eliminated, performed in different order, or performed in parallel, depending on the desired implementation.

Process 500 can be performed by a receiver in a memory, such as receiver 106 that includes circuit 108 described herein. Process 500 can begin at block 502. At block 502, the receiver can receive an analog signal. In one embodiment, the analog signal can be a single ended signal. In one embodiment, the analog signal can be a differential signal.

Process 500 can proceed from block 502 to block 504. At block 504, the receiver can apply a positive offset to the analog signal to generate a first internal signal. Process 500 can proceed from block 504 to block 506. At block 506, the receiver can apply a negative offset to the analog signal to generate a second internal signal. In one embodiment, applying the positive offset to the analog signal can include adding a predefined offset to the analog signal, and applying the negative offset to the analog signal can include subtracting the predefined offset from the analog signal.

Process 500 can proceed from block 506 to block 508. At block 508, the receiver can receive a selection signal. The selection signal can be a feedback of a previous digital signal outputted by the multiplexer. Process 500 can proceed from block 508 to block 510. At block 510, the receiver can select one of the first internal signal and the second internal signal. In one embodiment, the receiver can, in response to the previous digital signal indicating a high voltage, select the first digital signal. The receiver can further, in response to the previous digital signal indicating a low voltage, select the second digital signal.

Process 500 can proceed from block 510 to block 512. At block 512, the receiver can output the selected one of the first internal signal and the second internal signal as a third internal signal. Process 500 can proceed from block 512 to block 514. At block 514, the receiver can sample the third internal signal generate a digital signal that represents a decoded bit value of the analog signal. In one embodiment, the receiver can apply a first delay to the first internal signal, apply the first delay to the second internal signal, and apply a second delay to a strobe signal being used for sampling the third internal signal. In one embodiment, the receiver can sample the third internal signal according to a strobe signal.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An integrated circuit comprising:
a first summation circuit configured to:
receive an analog signal; and
apply a positive offset to the analog signal to generate a first internal signal;
a second summation circuit configured to:
receive the analog signal; and
apply a negative offset to the analog signal to generate a second internal signal;
a first slicer configured to sample the first internal signal to generate a first digital signal;
a second slicer configured to sample the second internal signal to generate a second digital signal; and
a multiplexer configured to:
receive a selection signal, wherein the selection signal is a feedback of a previous digital signal outputted by the multiplexer;
select a specific signal between the first digital signal and the second digital signal; and
output the selected specific signal as a digital signal that represents a decoded bit value of the analog signal.

2. The integrated circuit of claim 1, wherein the analog signal is a single ended signal.

3. The integrated circuit of claim 1, wherein the analog signal is a differential signal.

4. The integrated circuit of claim 1, wherein:
the first summation circuit is configured to apply the positive offset to the analog signal by adding a predefined offset to the analog signal; and
the second summation circuit is configured to apply the negative offset to the analog signal by subtracting the predefined offset from the analog signal.

5. The integrated circuit of claim 1, further comprising:
a first delay line configured to apply a first delay to the first internal signal;
a second delay line configured to apply the first delay to the second internal signal; and
a third delay line configured to apply a second delay to a strobe signal being used by the first slicer to sample the first internal signal and by the second slicer to sample the second internal signal.

6. The integrated circuit of claim 1, wherein the multiplexer is configured to:
in response to the previous digital signal indicating a high voltage, select the first digital signal; and
in response to the previous digital signal indicating a low voltage, select the second digital signal.

7. The integrated circuit of claim 1, wherein:
a first slicer is configured to sample the first internal signal according to a strobe signal; and
a second slicer configured to sample the second internal signal according to the strobe signal.

8. An integrated circuit comprising:
a first summation circuit configured to:
receive an analog signal; and
apply a positive offset to the analog signal to generate a first internal signal;
a second summation circuit configured to:
receive the analog signal; and
apply a negative offset to the analog signal to generate a second internal signal;
a multiplexer configured to:
receive a selection signal, wherein the selection signal is a feedback of a previous digital signal outputted by the multiplexer;
select one of the first internal signal and the second internal signal; and
output the selected one of the first internal signal and the second internal signal as a third internal signal; and
a slicer configured to sample the third internal signal to generate a digital signal that represents a decoded bit value of the analog signal.

9. The integrated circuit of claim 8, wherein the analog signal is a single ended signal.

10. The integrated circuit of claim 8, wherein the analog signal is a differential signal.

11. The integrated circuit of claim 8, wherein:
the first summation circuit is configured to apply the positive offset to the analog signal by adding a predefined offset to the analog signal; and
the second summation circuit is configured to apply the negative offset to the analog signal by subtracting the predefined offset from the analog signal.

12. The integrated circuit of claim 8, further comprising:
a first delay line configured to apply a first delay to the first internal signal;
a second delay line configured to apply the first delay to the second internal signal; and
a third delay line configured to apply a second delay to a strobe signal being used by the slicer to sample the third internal signal.

13. The integrated circuit of claim 8, wherein the multiplexer is configured to:
in response to the previous digital signal indicating a high voltage, select the first internal signal; and
in response to the previous digital signal indicating a low voltage, select the second internal signal.

14. The integrated circuit of claim 8, wherein the slicer is configured to sample the third internal signal according to a strobe signal.

15. A system comprising:
a controller configured to generate a strobe signal;
a transmitter configured to output an analog signal; and
a receiver configured to:
receive the analog signal from the transmitter through a channel;
apply a positive offset to the analog signal to generate a first internal signal;
apply a negative offset to the analog signal to generate a second internal signal;
sample at least one of the first internal signal and the second internal signal according to the strobe signal;
use a previous digital signal as a selection signal to select a specific signal that decodes the analog signal; and
based on the sample and the selection, generate a digital signal that represents a decoded bit value of the analog signal.

16. The system of claim 15, wherein the receiver comprises:
a first slicer configured to sample the first internal signal to generate a first digital signal;
a second slicer configured to sample the second internal signal to generate a second digital signal; and
a multiplexer configured to:
receive the previous digital signal as the selection signal, wherein the previous digital signal is outputted by the multiplexer;
select one of the first digital signal and the second digital signal as the specific signal; and
output the selected specific signal as a digital signal that represents a decoded bit value of the analog signal.

17. The system of claim 15, wherein the receiver comprises:
a multiplexer configured to:
receive the previous digital signal as the selection signal; and
select one of the first internal signal and the second internal signal as the specific signal; and
a slicer configured to sample the selected specific signal to generate the digital signal that represents the decoded bit value of the analog signal.

18. The system of claim 15, wherein the analog signal is a single ended signal.

19. The system of claim 15, wherein the analog signal is a differential signal.

20. The system of claim 15, wherein the receiver is further configured to:
apply a first delay to the first internal signal;
apply the first delay to the second internal signal; and
apply a second delay to the strobe signal to align the strobe signal with at least one of the first internal signal and the second internal signal being sampled.
